(19) United States
(12) Patent Application Publication
(10) Pub. No.: US 2021/0272983 A1
(43) Pub. Date: Sep. 2, 2021

(54) THREE-DIMENSIONAL FERROELECTRIC MEMORY

(71) Applicant: Seagate Technology LLC, Fremont, CA (US)

(72) Inventors: Ian J. Gilbert, Chanhassen, MN (US); Steven D. Granz, Shakopee, MN (US); Jon D. Trantham, Chanhassen, MN (US)

(21) Appl. No.: 17/084,940

(22) Filed: Oct. 30, 2020

Related U.S. Application Data
(60) Provisional application No. 62/982,516, filed on Feb. 27, 2020.

(51) Int. Cl. H01L 27/11597; H01L 27/24; H01L 45/00; H01L 27/1159; H01L 29/51; H01L 29/78

(52) U.S. Cl. CPC H01L 27/11597; H01L 27/2481; H01L 45/10; H01L 29/78391; H01L 45/147; H01L 27/1159; H01L 29/516; H01L 45/146

(57) ABSTRACT

A memory device has ferroelectric memory cells arranged into a three-dimensional (3D) structure. Each ferroelectric memory cell has a ferroelectric layer adapted to provide non-volatile storage of data. In some cases, each ferroelectric memory cell is arranged as a ferroelectric field effect transistor (FeFET) comprising a source region, a drain region, and a control gate region, the control gate region comprising the ferroelectric layer. In other cases, each ferroelectric memory cell is arranged as a ferroelectric tunnel junction (FTJ) comprising opposing conductive electrode layers between which the ferroelectric layer and a tunnel junction layer are contactingly disposed. The ferroelectric layer may be formed of HfO2, ZrO2, Hf1-xZxO2, etc. The tunnel barrier layer may be formed of Al2O3, MgO, SrTiO3, etc. The memory can be used as a substitute for DRAM, a main memory in a data storage device, a data cache, etc.

### RELATED APPLICATIONS

The present application makes a claim of domestic priority under 35 U.S.C. 119(e) to U.S. Provisional Patent Application No. 62/982,516 filed Feb. 27, 2020, the contents of which are hereby incorporated by reference.

### SUMMARY

Various embodiments of the present disclosure are generally directed to a non-volatile memory (NVM) in the form of a three-dimensional (3D) ferroelectric memory, useful in a variety of applications including but not limited to as a substitute for existing DRAM (dynamic random access memory), cached NVM, main store NVM, etc.

In some embodiments, an apparatus comprises a memory formed of ferroelectric memory cells arranged into a three-dimensional (3D) structure, each ferroelectric memory cell comprising a ferroelectric layer adapted to provide non-volatile storage of data.

In other embodiments, an apparatus comprises a non-volatile ferroelectric memory cell in a three-dimensional (3D) memory array in which nominally identical non-volatile ferroelectric memory cells are sequentially arranged in a spaced apart fashion along three orthogonal axes. Each of the ferroelectric memory cells has a ferroelectric layer adapted to provide non-volatile storage of data, a tunnel barrier layer contactingly engaging the ferroelectric layer, and opposing first and second conductive layers between which the ferroelectric layer and the tunnel barrier are disposed, the first conductive layer coupled to the ferroelectric layer, the second conductive layer coupled to the tunnel barrier.

These and other features and advantages of various embodiments can be understood from a review of the following detailed description in conjunction with the accompanying drawings.

### BRIEF DESCRIPTION OF DRAWINGS

FIG. 1 is a functional block diagram of a data processing system constructed and operated in accordance with various embodiments.

FIG. 2 is a schematic depiction of a one transistor, one capacitor (1T-1C) ferroelectric capacitor memory cell in some embodiments.

FIG. 3 depicts a ferroelectric tunnel junction (FTJ) in some embodiments.

FIGS. 4A and 4B are graphical depictions of band diagrams to illustrate operation of the FTJ of FIG. 3 in some embodiments.

FIG. 5 shows a ferroelectric field-effect transistor (FeFET) constructed and operated in accordance with some embodiments.

FIGS. 6A and 6B illustrate operation of the FeFET of FIG. 5 in some embodiments.

FIG. 7 is a three-dimensional (3D) isometric depiction of a vertical gate (VG) NAND FeFET memory in accordance with some embodiments.

FIG. 8 is a cross-sectional representation of a selected FeFET from FIG. 7.

FIG. 9 is a 3D isometric depiction of a horizontal NOR (HNOR) FeFET memory in accordance with some embodiments.

FIG. 10 is a cross-sectional representation of a selected FeFET from FIG. 9.

FIG. 11 is a 3D isometric depiction of a vertical cross point FTJ memory in accordance with some embodiments.

FIG. 12 is a cross-sectional representation of a selected FTJ from FIG. 11.

FIG. 13 is a 3D isometric depiction of a vertical FTJ memory in some embodiments.

FIG. 14 is a cross-sectional representation of a selected FTJ from FIG. 13.

FIG. 15 shows a functional block representation of a ferroelectric memory cell in conjunction with driver circuitry to program the cell and sense circuitry to sense the programmed state of the cell in accordance with some embodiments.

### DETAILED DISCUSSION

Various embodiments of the present disclosure are generally directed to systems and methods for arranging and using ferroelectric memory elements in a three-dimensional (3D) architecture.

Dynamic Random Access Memory (DRAM) technology provides a high speed volatile memory solution. DRAM memory cells each generally incorporate a single transistor (the selector) and a single capacitor (for storage). Because charge rapidly leaks off the capacitor, the state of the memory cell must be refreshed frequently, such as around every 64 milliseconds or so. A volatile memory such as DRAM thus provides fast data transfer performance, but tends to have a relatively large power consumption level and loses any stored information once power is removed from the memory.

DRAM is nearing the end of its lateral scaling roadmap and usually cannot be stacked into 3D architectures like NAND flash. Current generation densities of DRAM are limited to on the order of around 32-64 Gb/die (1 Gb, gigabit=1×10¹² bits). There is a need for improved memory solutions with the same, or even faster transfer performance, that have greater storage densities, and which consume less power.

Various embodiments of the present disclosure are generally directed to novel arrangements of ferroelectric memory to address these and other limitations of the existing art. The ferroelectric memory arrangements proposed herein are suitable for a number of applications, including but not limited to as a replacement for DRAM (e.g., local processor memory applications). Other use cases are contemplated as well, including caches, buffers, main memory storage, etc.

As described herein, ferroelectric memory cells can be configured to operate as a random access memory similar in construction to DRAM, but with each cell using a ferroelectric layer rather than a dielectric layer. Ferroelectric memory elements can also be arranged as ferroelectric field-effect transistors (FeFETs) and ferroelectric tunnel junctions (FTJs) in three-dimensional architectures to produce dense, non-volatile, low latency memory structures.

The ferroelectric memory cells encode information in the direction of the electric polarization of a ferroelectric material. One promising material for this type of memory is hafnium oxide (HfO2), which is CMOS-compatible and takes on a ferroelectric orthorhombic crystal structure under appropriate combinations of thickness, strain, and dopants. The ferroelectric polarization of an HfO2 layer can be switched very rapidly, in less than one nanosecond in some cases, so the write and erase speeds of HfO2-based memory cells rival, and can even exceed, speeds of conventional DRAM.

HfO2 retains ferroelectricity in film thicknesses under 10 nm, and it can be deposited conformally via atomic layer deposition, which enables the fabrication of high-density three-dimensional memory architectures. Other suitable ferroelectric materials are disclosed and can be used, however, including but not limited to ZrO2, Hf1-xZxO2, or other materials and alloys. These materials may be doped with other elements, e.g., Si, Ge, Al, Ti, Sc, Y, La, Ce, Gd, Nb, Sr, Ba, N, etc. These are merely illustrative and are not necessarily limiting alternatives.

A number of embodiments are proposed herein. Without limitation, a first embodiment is generally directed to FeFETs arranged in a three-dimensional (3D) vertical gate (VG) NAND architecture. A second embodiment utilizes FeFETs arranged in a 3D horizontal NOR (HNOR) configuration. A third embodiment is directed to ferroelectric tunnel junctions (FTJs) in a cross-point array. A fourth embodiment uses FTJs as memory cells in an architecture adapted from 3D NAND flash memory. Other configurations and combinations of the same will readily occur to the skilled artisan in view of the present disclosure.

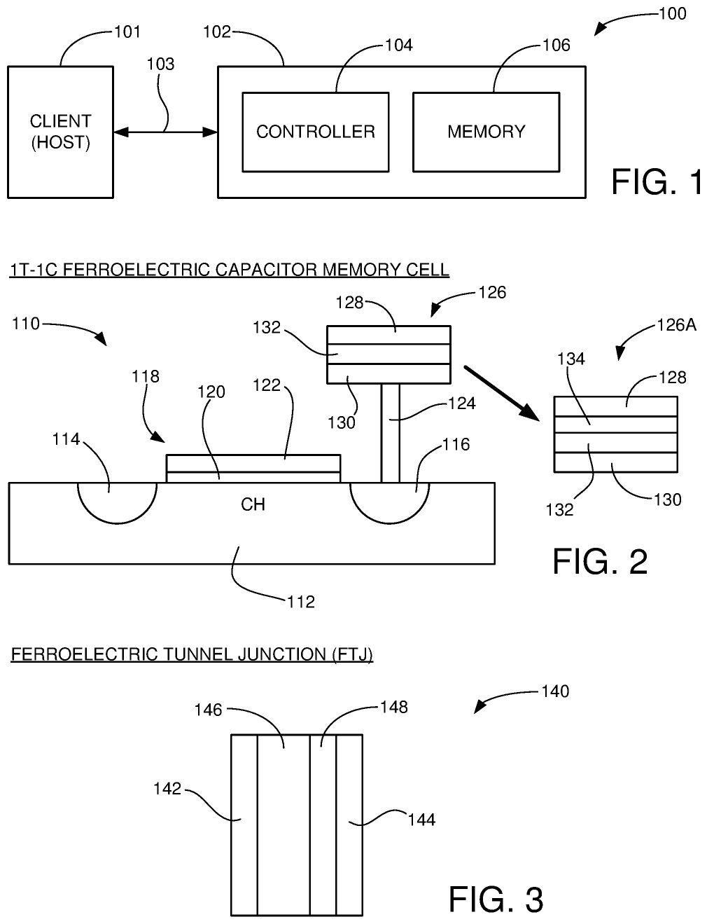

FIG. 1 shows a generalized functional block diagram for a data processing system 100 constructed and operated in accordance with various embodiments. FIG. 1 has been provided to provide an example environment in which various embodiments of the present disclosure can be utilized. Other operational environments are contemplated and will readily occur to the skilled artisan in view of the present discussion, so it will be understood that FIG. 1 is merely illustrative and not limiting.

The system 100 includes a client (host) device 101 that communicates with a data storage device 102 via an interface 103. The client device 101 may take the form of a personal computer, a smart phone, a workstation, a tablet, a laptop, a gaming system, a microcontroller, a server, an edge device, an Internet of Things (IoT) device, etc. It is contemplated albeit not required that the client 101 is a user device accessed by a user.

The data storage device 102 is configured to store and retrieve data utilized by the user of the client device 101 and may be a local processor memory, a data cache, a server cache, a RAID storage system, a cloud storage system, a solid-state drive (SSD), a hard disc drive (HDD), a hybrid storage device, an array of storage devices, a portable thumb (e.g., USB) drive, etc. The interface 103 can take substantially any form including but not limited to a local wired or wireless interface, a local area network (LAN), a wide area network (WAN), a cloud computing interface, the Internet, etc.

Of interest is the data storage device 102, which is shown to include a controller 104 and a memory 106. The controller 104 can include one or more programmable processors that execute program instructions stored in a local memory to carry out various functions, including the control of data transfers between the memory 106 and the client 101 across the interface 103. As desired the controller 104 can additionally or alternatively be realized using hardware circuits.

The memory 106 can include any number of useful forms including local memory for the controller, cache memory, buffer, main storage, etc. While not limiting, it is contemplated that the memory 106 will include ferroelectric memory to provide non-volatile memory (NVM) storage for data utilized or otherwise processed by the controller 104. As will be recognized, the term “non-volatile” describes a memory that continues to retain information stored therein even after the removal of applied power.

FIG. 2 is a schematic representation of a one transistor, one capacitor (1T-1C) ferroelectric capacitor memory cell 110 in accordance with some embodiments. The cell 110 can be used as a replacement for conventional DRAM memory cells, and exhibits comparable or improved performance over such DRAM cells. The memory cell 110 includes a semiconductor substrate 112 with respectively doped source 114 and drain 116 regions. An intervening channel region (CH) extends therebetween adjacent a gate structure 118. It is contemplated although not necessarily required that the substrate 112 may be p doped and the source and drain regions 114, 116 may be n doped.

The gate structure 118 includes an interlayer 120 and a conductive control gate region 122. An interconnect structure 124 supports a capacitive structure 126 including opposing capacitive plates 128, 130 separated by an intervening ferroelectric layer 132. While FIG. 2 shows a planar capacitor with flat conductive electrodes and an intervening ferroelectric layer, an extended three-dimensional (3D) structure can be used, such as by using concentric electrode and ferroelectric layers (e.g., rings, etc.).

An alternative construction for the capacitive structure can be provided, as depicted by alternative capacitive structure 126A. In this case, it may be advantageous to insert a nonferroelectric layer 134, such as a dielectric layer, next to the ferroelectric layer 132 and between the capacitive plates 128, 130. The non-ferroelectric layer 134 may be adjacent either capacitive plate (e.g., above or below the ferroelectric layer 132) as required.

The ferroelectric memory cell 110 is an NVM memory cell that encodes information in the direction of the electric polarization of the ferroelectric material that makes up layer 132. As noted above, one suitable material for the layer 132 is, or comprises, hafnium oxide (HfO2), which can retain ferroelectricity in film thicknesses under 10 nm, can be deposited conformally via atomic layer deposition, and enables fabrication in a number of different high-density three-dimensional memory architectures such as described below.

Existing DRAM fabrication processes can be used to generate memory cells such as 110 but with the substitution of a ferroelectric material such as HfO2 for the layer 132 to form NVM modules with the same, or better, properties than conventional DRAM. Other suitable ferroelectric materials for the layer 132 can be used. As noted above, these can include, but are not limited to, combinations or alloys that include HfO2, ZrO2, Hf1-xZxO2, or other materials or alloys. These materials may be doped with other elements, e.g., Si, Ge, Al, Ti, Sc, Y, La, Ce, Gd, Nb, Sr, Ba, N, etc., for improved ferroelectric properties.

As will be recognized by those skilled in the art, a conventional DRAM memory cell stores data in terms of the presence or lack of an electrical charge in the capacitor (e.g., structure 126), with the lack of charge in general representing a first logical value (e.g., logical 0). and the presence of charge representing a second logical value (e.g., logical 1). Other conventions can be used.

Programming a DRAM memory cell can be carried out by activating the associated control transistor, draining the cell to write a logical 0, or applying current to write a logical 1. Reading the DRAM memory cell involves activating the transistor and draining the charge from the capacitor to a sense amplifier. If a pulse of charge is detected, the state is determined to be a logical 1; if no pulse of charge is detected, the state is determined to be logical 0. It will be noted that the read operation is destructive, so that if a logical 1 is detected the capacitor is recharged to restore the stored value. As noted above, the leaking nature of a typical DRAM cell requires continual read and refresh operations to retain the stored information.

The 1T-1C ferroelectric memory cell 110 operates in a similar fashion. To program the cell 110, an applied electric field across the layer 132 via electrodes 12$, 130 causes dipoles in the layer 132 to align with the applied field direction (e.g., up or down). However, unlike a typical DRAM cell, once the electric field is removed, the dipole alignment is retained within the layer 132 of the ferroelectric cell 110. Logical 0 and 1 states are programmed responsive to the polarization of the layer 132.

To subsequently read the cell 110, the transistor is placed in a conductive source-drain state. If the layer 132 is in a first logical state (e.g., logical 0), no pulses will be detected by a sense amplifier connected to the transistor. If the layer 132 is in a second logical state (e.g., logical 1), the re-orientation of the atoms in the layer 132 will induce a small pulse of current, which can be detected as before. Depending on the ferroelectric material used, the reading process may or may not be destructive, so a refresh operation may or may not be required to restore the previous state.

While the present disclosure contemplates the use of ferroelectric memory in a memory cell such as disclosed in FIG. 2, other configurations are contemplated that can further enhance the efficiency and performance of a memory. FIG. 3 shows a schematic representation of a so-called ferroelectric tunnel junction (FTJ) 140. The FTJ 140 is a two-terminal device with outer conductive electrode layers 142, 144, an inner (programming) layer of ferroelectric material 146, and an optional tunnel barrier layer 148. The tunnel barrier layer 148 is contemplated but not necessarily required as a separate layer, and may be any suitable material such as but not limited to a non-ferroelectric material, a dielectric material, etc.

With the appropriate choice of electrode materials, tunnel barrier, and ferroelectric layer, the resistance of the FTJ can be made to depend on the orientation of the ferroelectric polarization of the ferroelectric layer 146. Stated another way, an FTJ such as the FTJ 140 operates in a manner similar to magnetic tunnel junctions (FTJs), and will present different electrical resistances between electrodes 142, 144 based on the programmed polarization of the ferroelectric layer 146. The differences in electrical resistance will vary depending on construction, but differential resistance values can be greater than 10⁴ ohms.

The programmed state of the ferroelectric layer 146 can be established by supplying a voltage of suitable amplitude, duration and polarity across the respective electrode layers 142, 144. A first polarity provides the layer 146 with a first, higher electrical resistance, and an opposing second polarity provides the layer 146 with a second, lower electrical resistance. The programmed states of the layer 146 can be accomplished and reversed (overwritten) using moderate magnitudes and dwell times.

This can accordingly provide an efficient and effective way to detect programmed states within the FTJ (e.g., a high resistance is a first logical value, a low resistance value is a different logical value). At this point it will be understood that the particular construction of each of the respective layers 142-148 is not limited, so long as the ferroelectric polarization of layer 146 establishes different electrical resistances between electrodes 142 and 144. Example materials are noted above. As before, the read operation may be destructive or non-destructive, so that a refresh operation may or may not be required.

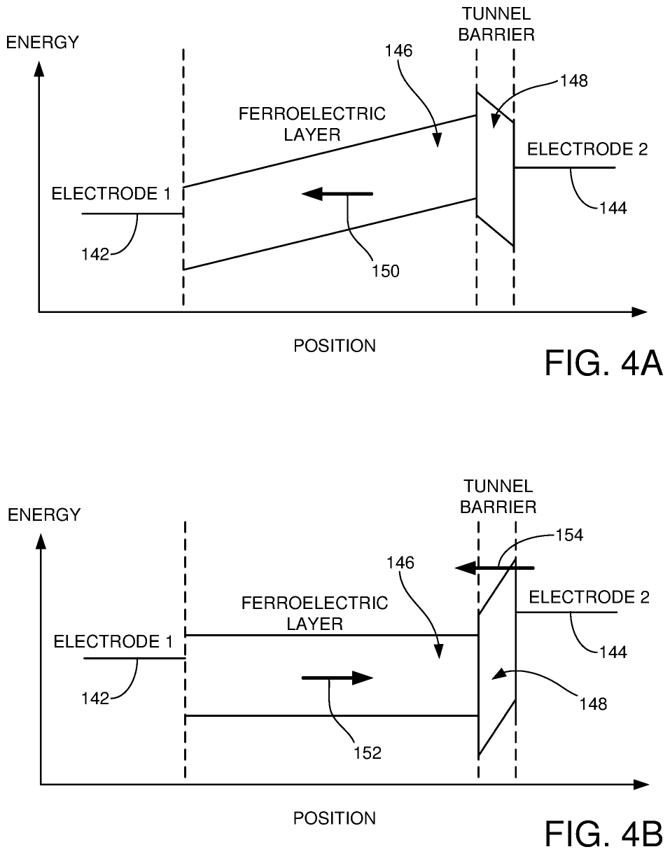

FIGS. 4A and 4B show graphical representations of the operation of an FTJ such as the FTJ 140 in FIG. 3 in accordance with some embodiments. FIG. 4A shows the programmed state of the FTJ in a first direction (as indicated by polarization arrow 150) and FIG. 4B shows the programmed state of the FTJ in an opposing second direction (polarization arrow 152). Arrow 154 indicates electrical current flowing when the barrier height is reduced by appropriate orientation of the ferroelectric polarization.

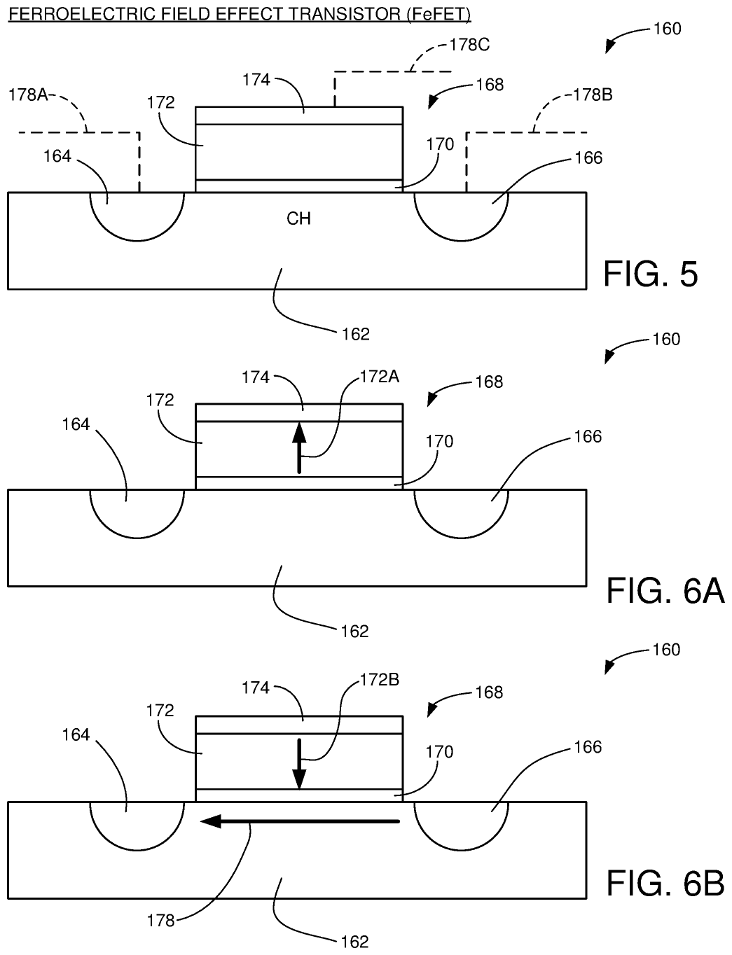

FIG. 5 shows another embodiment in which a ferroelectric field-effect transistor (FeFET) 160 is created by replacing the gate dielectric material of a conventional FET with HfO2 (or other suitable ferroelectric material). It will be appreciated that the FeFET 160, as well as the other structures illustrated in the various drawings in the present discussion, are not necessarily drawn to scale.

The FeFET 160 in FIG. 5 includes a substrate 162 similar to the substrate 112 in FIG. 2. Respective source and drain regions 164, 166 form a channel (CH) adjacent a gate structure 168. The gate structure 168 includes an interlayer 170, a ferroelectric layer 172 and a gate layer 174. The interlayer 170 can also be characterized as a tunnel barrier layer. Respective conductive (electrode) layers 176A, 176B and 176C (represented via broken lines) are provided to interconnect the respective source, drain and gate regions of the FeFET 160 to control and sensing circuitry (not separately shown in FIG. 5).

The ferroelectric polarization of layer 172 modulates the carrier concentration in the transistor channel depending on its programmed orientation, providing a transistor whose source-drain current depends on the history of program/erase pulses provided to the gate, yielding low-latency, nonvolatile storage. More particularly, FIG. 6A shows the FeFET 160 with the ferroelectric layer 172 programmed in a first direction (arrow 172A), resulting in a first conductivity level through the source-drain channel. FIG. 6B shows the FeFET 160 with the ferroelectric layer 172 programming in the opposing second direction (arrow 172B). As indicated by current flow arrow 178 in FIG. 6B, the second programming state 172B provides higher conductivity (lower resistance) as compared to the first programming state 172A. The programmed state of the cell can be determined responsive to the sensed flow of source-drain current.

As mentioned previously, the present disclosure contemplates several variations on the ferroelectric film or film stack used in FTJs and FeFETs, all of which fall within the scope of this disclosure. The ferroelectric material may be, but is not limited to HfO2, ZrO2, Hf1-xZxO2, or other materials and alloys thereof. These materials may be doped with other elements, e.g., Si, Ge, Al, Ti, Sc, Y, La, Ce, Gd, Nb, Sr, Ba, N, etc., for improved ferroelectric properties. The conductor used as the electrode of an FTJ or the gate of a FeFET can also be selected to promote the formation of the ferroelectric orthorhombic phase of HfO2 as well as to create a level of strain appropriate for enhancing ferroelectric properties. Suitable materials may include, but are not limited to, TiN, TaN, Pt, Ag, CrRu, CrMo, CrW, CrTi, and RuAl.

A subsequent annealing step may be necessary to develop the appropriate crystal structure in the ferroelectric layer. FTJs can benefit from some form of asymmetry to operate properly, which may be achieved by providing electrodes of dissimilar materials (e.g., different work functions). The ferroelectric layer may be a single ferroelectric film, a multilayer comprised of ferroelectric materials of different combinations, or a multilayer comprised of both ferroelectric and dielectric films. Such multilayers enable the memory cell to be programmed to multiple levels for operation analogous to multi-level NAND flash (e.g., MLC, TLC, QLC, etc.) where 2^{N} discrete program levels are used to store N bits (e.g., a TLC uses 8 levels to program 3 bits, a QLC uses 16 levels to program 4 bits, and so on).

The addition of a dielectric (tunnel barrier) layer (e.g., Al2O3, MgO, SrTiO3, etc.) to a FTJ stack may be desirable to allow for greater tenability by partially decoupling the tunneling properties from the ferroelectric properties. An antiferroelectric layer (e.g., ZrO2) may be used in the place of the ferroelectric layer if an internal bias field, e.g., from two dissimilar electrodes, is introduced in order to shift its hysteresis loop to enable the storage of binary information. While specific examples of material stacks are given in the embodiments below, any of the variations described here may be substituted while remaining within the scope of this disclosure.

The following discussion will now address specific embodiments that can utilize FTJs and FeFETs as described above in novel three-dimensional (3D) architectures. These can include NAND, NOR, and cross-point arrangements to provide non-volatile, low-latency memory with a scaling path that extends far beyond the density limits of current generation 1T-1C DRAM designs.

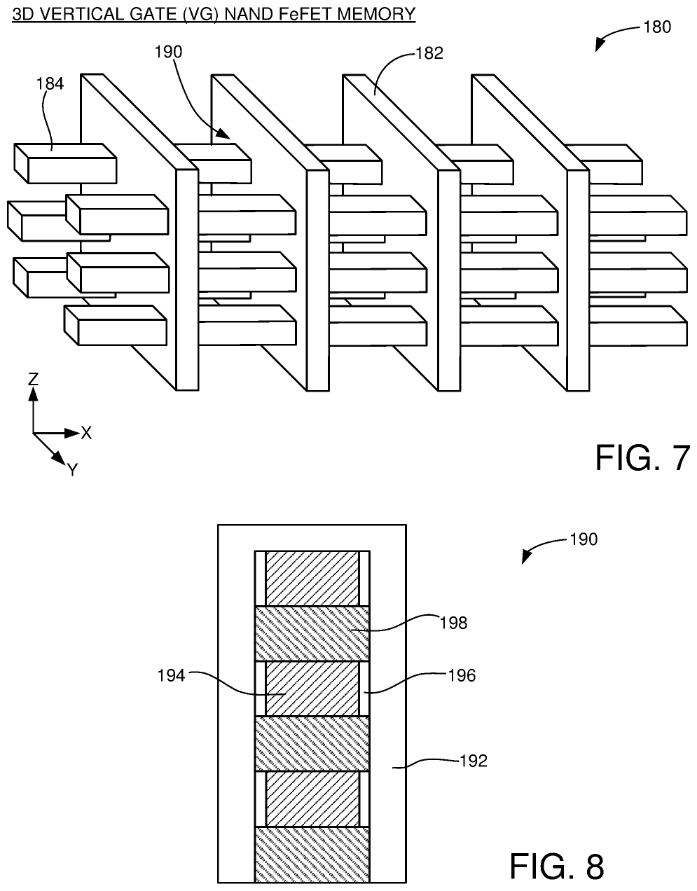

FIG. 7 is an isometric representation of a portion of a 3D vertical gate (VG) NAND FeFET memory 180 in accordance with some embodiments. This embodiment utilizes FeFETs arranged in a three-dimensional vertical-gate NAND architecture. FIG. 8 shows a cross-section of a selected one of the FeFETs depicted in FIG. 7.

Vertically extending layers 182 represent gate structures (vertical gates, or VGs). Horizontally extending layers 184 represent active layers. FeFETs 190 are arranged at each intersection of a corresponding pair of vertical and horizontal layers 182, 184. It will be noted that the FeFETs 190 are arranged in a 3D spaced apart relation along multiple orthogonal axes (e.g., axes X, Y and Z as shown). This same relation is provided for each of the embodiments to follow below.

One FeFET 190 from FIG. 7 is depicted in the cross-sectional view of FIG. 8. Composite elements shown in FIG. 8 include a vertical gate 192 (portion of 182), active strips 194 (portion of 184), ferroelectric layers 196, and insulating layers 198.

3D VG NAND structures such as 180 can be fabricated using fabrication methods that are currently used to form charge-trapping (ONO) flash memory cells (with the changes described herein to provide FeFET based memory arrays). An example fabrication process can be described as follows.

First, CMOS peripheral circuitry (switches, decoders, sense amps, etc.) are fabricated on an underlying substrate (wafer). Alternating, repeating layers of a doped semiconducting material such as p-doped polysilicon and an insulating material such as silicon oxide are deposited. Next, vertical trenches are etched through all the layers. At this point, for conventional 3D VG NAND with charge trapping memory cells, charge trapping layers (e.g., ONO) are conformally deposited on the side walls of the trenches and appropriate select transistors are formed at the ends of the strings via ion implantation or similar process.

A conducting material, e.g., doped polysilicon, is deposited in the trenches and patterned into word line planes perpendicular to the trenches defining the horizontal channels. In this embodiment, instead of a charge trapping layer, a ferroelectric layer, e.g. an 8 nm film of Hf0.5Zr0.5O2 is deposited. This is followed by deposition of an appropriate material, e.g., TiN, to promote development of ferroelectric orthorhombic Hf0.5Zr0.5O2, which is then patterned into word line planes.

Programming is accomplished by applying a positive programming pulse (e.g., +10V) to the word line of the selected cell while holding the channel at 0 V. A smaller inhibit voltage (e.g., +5 V) may be applied to the active layers of bits sharing the same word line so that they are not disturbed by the program operation.

Erasing is accomplished by applying an electric field of opposite polarity, e.g., +10 V to the channel while grounding the word line, or −10 V to the word line while grounding the channel. Again, appropriate inhibit voltages must be applied to the other transistors sharing the same word line so that they are not disturbed by the erase operation.

A cell is read by applying a small pass voltage (e.g., 3 V) to all the transistors sharing an active layer with the transistor to be read (e.g., pass voltage is applied to the rest of the NAND string), and the resulting cell current is measured while the gate voltage of the transistor of interest is swept. The gate voltage at which the transistor turns on may be identified by sense amplifiers and other CMOS peripheral circuitry and can be compared either to a single threshold for SLC operation or to multiple thresholds so that multiple bits may be recorded in each memory cell.

For faster read performance, multiple cells, such as two cells, may be used per bit, with each cell programmed differently (one cell programmed high and the other cell programmed low for a 1, and vice-versa for a 0). On a read, the stored value can be determined by sensing the two cells differentially. Other arrangements can be used. Note that these various SLC, MLC, and ½-bit per cell arrangements, as well as other storage arrangements, also apply to the other embodiments presented herein.

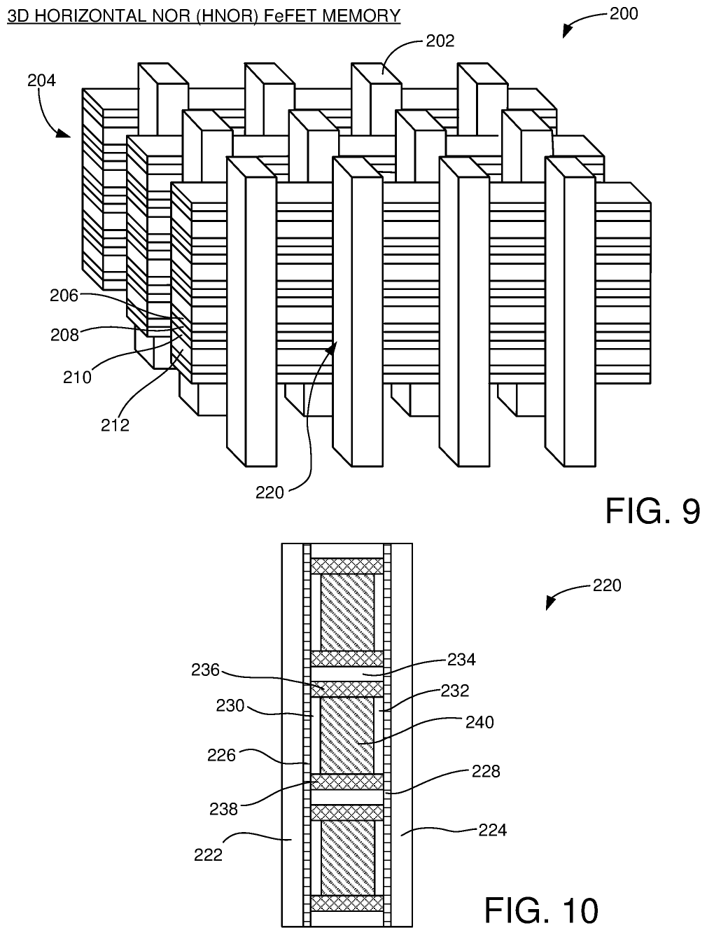

FIG. 9 shows an isometric schematic depiction of another memory 200 constructed and operated in accordance with some embodiments. The memory 200 in FIG. 9 is characterized as a three-dimensional (3D) horizontal NOR (HNOR) FeFET memory array. This arrangement is suitable as a NOR flash replacement, as well as in other applications, and can be readily fabricated using existing processes (as modified herein) well known to those skilled in the art. A cross-sectional view of one of the FeFETs in FIG. 9 is provided in FIG. 10.

Elements in the memory 200 shown in FIG. 9 include vertically extending layers 202 configured to operate as word lines. A number of stacks 204 are coupled between adjacent sets of the vertical layers 202. Each stack includes respective, multiple sets of drain layers 206, bit lines 208, source layers 210, and channel/isolation layers 212. FeFETs 220 are located at the conjunction of each vertically extending layer and each horizontally extending set of layers, as indicated by arrow 220.

FIG. 10 shows a number of stacked FeFETs 220 from FIG. 9. Depicted regions include a left-side word line 222; a right-side word line 224; ferroelectric layers 226, 228; a left-side channel 230; a right-side channel 232; bit, source and drain lines 234, 236, 238; and interior isolation regions 240.

An exemplary fabrication process to form the memory 200 of FIGS. 9-10 can be as follows. First, CMOS peripheral circuitry (decoders, sense amps, etc.) are fabricated on an underlying wafer. Repeating layers of N+, P−, N+ polysilicon and optionally metal (e.g., W) bit lines are deposited. The N+ layers form the sources and drains of the memory cell transistors, while the edges of the P− layers form the channels. The metal reduces the bit line resistance and consequently the RC delay associated with the bit line, thus reducing the latency.

Stacks of bit lines are separated by etching vertically down to the substrate. The transistor gates are deposited conformally (e.g., via atomic layer deposition (ALD)). In the prior art, the gate structure was, e.g., a charge trap layer (ONO). In this embodiment, a conformally-deposited ferroelectric layer is used instead. A variety of materials and structures may be used for the ferroelectric film. By way of example, an 8 nm layer of Hf0.5Zr0.5O2 may be used.

After the ferroelectric film is deposited, metal gates and word lines are deposited and patterned. The metal may be chosen to produce the appropriate crystalline texture to promote the formation of the ferroelectric orthorhombic phase of HfO2 and related ferroelectrics. These materials include, but are not limited to, TiN, Pt, Ag, CrRu, CrMo, CrW, CrTi, and RuAl. A subsequent annealing step may be necessary to develop the appropriate crystal structure in the ferroelectric layers.

Programming of the respective FeFETs 220 can be accomplished by applying a positive programming voltage pulse (e.g., +10V) to the word line of the selected transistor while holding the source and drain (bit line) of the selected transistor at 0 V. The bit lines of the unselected transistors are held at an intermediate inhibit voltage (e.g., +5V) to prevent them from being written. An erase operation simply reverses the program operation, either with a negative voltage (e.g., −10V) applied to the gate while holding the source and drain at 0, or with a positive voltage (e.g., +10V) applied simultaneously to the source and drain while the gate is grounded. In either erase scheme, appropriate inhibit voltages must again be applied to the unselected transistors to prevent their state from being disturbed.

Reading a memory cell is accomplished by applying a small, positive voltage (e.g., +0.5 V) to the drain and holding the source at 0V while a small voltage (e.g., 2 V) may be applied to the gate of the selected transistor as well. To prevent other cells sharing bit lines with the selected cell from also being read, the gates of these cells are held at 0 V by grounding their word lines. The state of the memory cell is determined by measuring the current flowing through the selected cell, e.g., with sense amplifiers and other peripheral CMOS circuitry familiar to one of ordinary skill in the art.

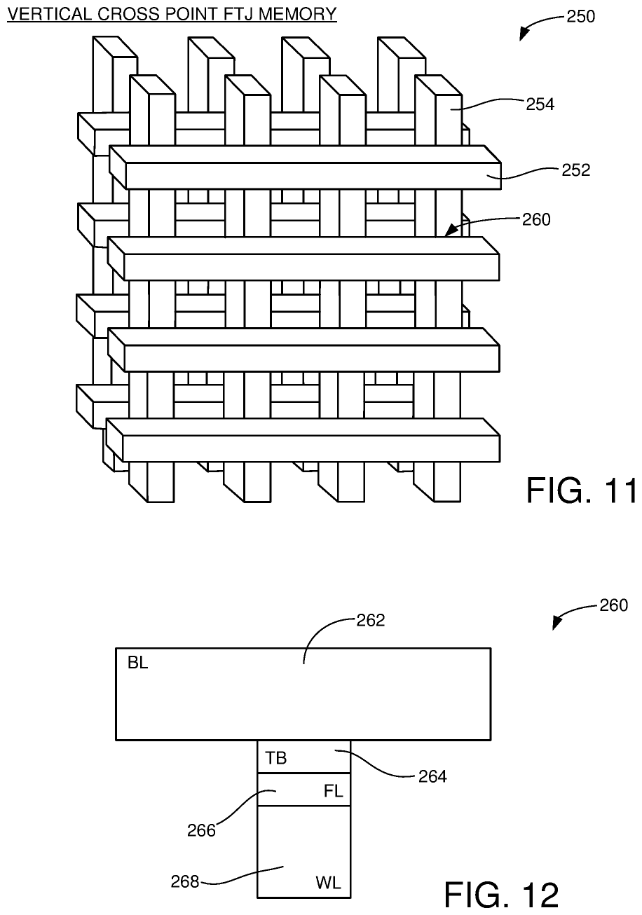

FIG. 11 provides another alternative embodiment comprising a vertical cross point FTJ memory 250. Unlike the previous embodiments that utilized FeFET constructions, this embodiment is directed to FTJs similar to the FTJ 140 in FIG. 3. The memory 250 includes horizontal layers 252 characterized as bit lines and vertical layers 254 characterized as word lines. FTJs are located at each junction, as generally indicated at 260.

FIG. 12 provides a cross-sectional representation of a selected FTJ 260 from FIG. 11. The FTJ includes a bit line (BL) 262, a tunnel barrier (TB) layer 264, a ferroelectric layer (FL) 266 and a word line (WL) 268. This facilitates a simple and highly dense construction since, in essence, the tunnel barrier and ferroelectric layers 264, 266 are sandwiched between each junction of bit and word lines 262, 264.

The memory array 200 can be fabricated using standard semiconductor memory fabrication processes familiar to one of ordinary skill in the art, as modified herein. First, CMOS peripheral circuitry (decoders, sense amps, etc.) are fabricated on a wafer. A stack of alternating layers of a conductor and an insulator are deposited. By way of example, alternating layers of doped n-type polysilicon and silicon oxide are deposited, e.g., by chemical vapor deposition. The conducting layers will form the bit lines for the array.

Next, parallel vertical trenches are etched down to the substrate. A conformal deposition technique such as ALD is used to deposit the barrier of a ferroelectric tunnel junction. By way of example, a 4 nm layer of Al2O3 (for the tunnel barriers) followed by an 8 nm layer of Hf0.5Zr0.5O2 (for the ferroelectric layers) are deposited, though any number of combinations of ferroelectric materials, tunnel barrier materials, and multilayers thereof could be used. Finally, another conducting material (e.g., TiN) is deposited in the trenches and patterned into the vertical word lines.

To write data to the memory 250, an electric field is applied across the associated memory cell 260 by applying a voltage (e.g., 6 V) to the word line while grounding the bit line, or vice versa. The electric field should exceed the coercive field of the ferroelectric film in order to reverse its polarization. In order to prevent memory cells sharing the same word or bit line from being disturbed, an inhibit voltage (e.g., 3 V) may be applied to the other word or bit lines so that the electric fields across the unselected cells do not exceed the coercive field of the ferroelectric film.

The memory cell 260 is subsequently read by placing a smaller (e.g., 2 V) voltage across the memory cell and reading the resulting current using sense amplifiers and other peripheral CMOS circuitry well known to those of ordinary skill in the art.

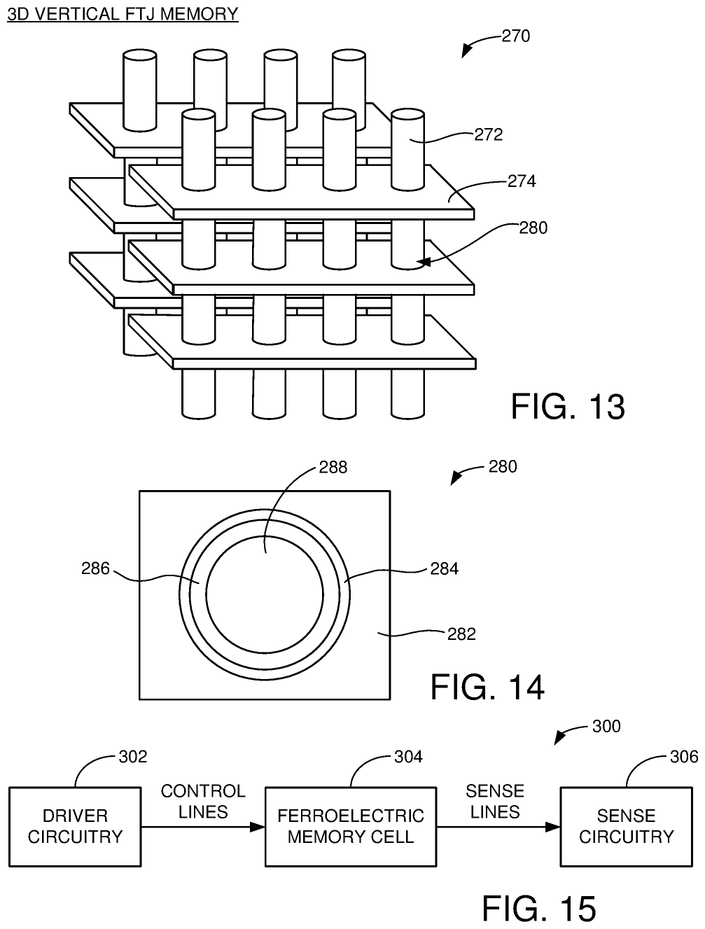

FIG. 13 provides yet another memory 270 formed from FTJs as described herein. This embodiment utilizes ferroelectric tunnel junctions as the memory cell in an architecture adapted from 3D NAND flash architecture. A cross sectional view is provided in FIG. 14. The memory 270 can be characterized as a 3D vertical FTJ memory.

The memory 270 as depicted has vertically extending, curvilinear (e.g., cylindrically shaped) layers 272 characterized as word lines, and horizontally extending, rectilinear planar layers 274 characterized as bit lines. An FTJ 280 is provided at the intersection of each of these respective members. As an aside, it will be noted that the use of rectilinear or curvilinear members can be modified in each of the various embodiments that have been presented, as can other features, orientations and arrangements. Accordingly, the various embodiments are merely illustrative and not limited.

A selected one of the FTJs 280 is depicted in FIG. 14. Features include a bit line region 282 (corresponding to the horizontal plate layers 274 in FIG. 13), a circumferentially extending tunnel barrier layer 284, a circumferentially extending ferroelectric layer 286, and an interior word line 288 (corresponding to the vertical cylindrical layers 272). The concentric arrangement of FIG. 14 provides a space efficient and effective architecture.

The memory array 270 is fabricated using standard semiconductor memory fabrication processes familiar to one of ordinary skill in the art, as modified herein. First, CMOS peripheral circuitry (decoders, sense amps, etc.) are fabricated on a wafer. A stack of alternating layers of a conductor (e.g., doped polysilicon) and an insulator (e.g., SiO2) are deposited. The conducting layers will form the bit lines for the array.

Next, holes are etched through the entire stack down to the substrate. Slits separating groups of holes from each other may also optionally be etched at this point. At this point, a conformal deposition technique such as ALD is used to deposit the barrier of a ferroelectric tunnel junction. By way of illustration, a 4 nm layer of Al2O3 tunnel barrier layer followed by an 8 nm layer of Hf0.5Zr0.5O2 ferroelectric layer is deposited, though any number of combinations of ferroelectric materials, tunnel barrier materials, and multilayers thereof could be used.

Another conducting material (e.g., TiN) is deposited into the hole array. This conducting material may either entirely fill the rest of the hole or comprise a cylindrical shell concentric with the ferroelectric tunnel junction stack, and in the latter case the central hole may optionally be filled with an insulating material (similar to the Macaroni body vertical transistors used in conventional charge-trapping 3D NAND flash memory). Finally, conducting word lines are deposited and patterns to electrically contact the central conducting electrodes in the memory holes.

To write data, an electric field is applied across the memory cell by applying a voltage (e.g., 5 V) to the word line while grounding the bit line, or vice versa. Depending on the electrical properties of the memory cells, the programming scheme used, and the number and placement of isolation slits, it may be necessary to apply an inhibit voltage to unselected memory cells to prevent program disturb. The memory cell is read by placing a smaller (e.g., 2 V) voltage across the FTJ and reading the resulting current using sense amplifiers and other peripheral CMOS circuitry well known to those of ordinary skill in the art.

It will now be appreciated that the various embodiments of the present disclosure provide a number of benefits over the existing art. The use of ferroelectric layers and structures in a number of novel FeFET and FTJ arrangements as disclosed herein can provide numerous cost effective, compact and fast performance memory applications. Some embodiments have been presented in the context of a DRAM substitute, so that the various memory arrays could be readily incorporated into an existing SOC (system on chip), ASIC (application specific integrated circuit) or other integrated application to provide local fast and reliable memory for a processor.

However, the present disclosure is not so limited; the skilled artisan will immediately recognize that the various structures provided have numerous other valuable applications for any number of other environments. Such environments include, but are not limited to, main memory for a data storage device (e.g., as a replacement for NOR or NAND flash in an SSD or hybrid data storage device), a data cache, a RAID controller storage space, a mass storage environment, a cloud computing environment, an edge computing environment, a portable USB storage device, an IoT device, local memory for a portable storage device (e.g., smart phone, tablet, laptop), etc.

The terms “horizontal” and “vertical” as used herein will be understood as relative terms with regard to relative orthogonality and do not necessarily require absolute orientation with respect to the center of the earth. Accordingly, horizontal and vertical elements can be oriented in any respective orientations so long as the respective elements are nominally orthogonal to one another in the context in which these terms are used.

It is to be understood that even though numerous characteristics and advantages of various embodiments of the present disclosure have been set forth in the foregoing description, this description is illustrative only, and changes may be made in detail, especially in matters of structure and arrangements of parts within the principles of the present disclosure to the full extent indicated by the broad general meaning of the terms wherein the appended claims are expressed.

What is claimed is:

1. An apparatus comprising a memory formed of ferroelectric memory cells arranged into a three-dimensional (3D) structure, each ferroelectric memory cell comprising a ferroelectric layer adapted to provide non-volatile storage of data.

2. The apparatus of claim 1, wherein each ferroelectric memory cell is arranged as a ferroelectric field effect transistor (FeFET) comprising a source region, a drain region, and a control gate region, the control gate region comprising the ferroelectric layer.

3. The apparatus of claim 1, wherein each ferroelectric memory cell is arranged as a ferroelectric tunnel junction (FTJ) comprising opposing conductive electrode layers between which the ferroelectric layer and a tunnel junction layer are contactingly disposed.

4. The apparatus of claim 1, wherein the ferroelectric layer comprises at least a selected one of HfO2, ZrO2, or Hf1-xZxO2, and wherein each ferroelectric memory cell further comprises a tunnel barrier layer contactingly adjacent the ferroelectric layer comprising at least a selected one of Al2O3, MgO, or SrTiO3.

5. The apparatus of claim 1, wherein the ferroelectric layer is configured to store multiple bits of data.

6. The apparatus of claim 1, wherein the ferroelectric layer is configured to store less than a full bit of data.

7. The apparatus of claim 1, wherein the memory is characterized as a 3D vertical gate (VG) NAND ferroelectric field effect transistor (FeFET) memory, the memory arranged as a plurality of vertically extending, planar gate structures intersected by a plurality of horizontally extending access control lines, wherein at least one FeFET is arranged at each intersection of the horizontally extending control lines and the vertically extending planar gate structures.

8. The apparatus of claim 1, wherein the memory is characterized as a 3D horizontal NOR (HNOR) ferroelectric field effect transistor (FeFET) memory, the memory arranged as a plurality of vertically extending layers configured to operate as word lines, a plurality of stacks of layers between adjacent pairs of the vertically extending layers, and a plurality of FeFETs at each connecting interface between an associated word line and an associated stack.

9. The apparatus of claim 8, wherein each stack comprises multiple sets of repeating layers comprising a drain layer, a bit line layer, a source layer and a channel/isolation layer.

10. The apparatus of claim 1, wherein the memory is characterized as a vertical cross point ferroelectric tunnel junction (FTJ) memory, comprising a plurality of spaced apart vertically extending layers characterized as word lines and a plurality of spaced apart horizontally extending layers characterized as bit lines, wherein at each intersection of the respective vertically extending layers and the horizontally extending layers an FTJ memory cell is formed, each FTJ memory cell comprising a tunnel junction layer and the ferroelectric layer.

11. The apparatus of claim 1, wherein the memory is characterized as a vertical ferroelectric tunnel junction (FTJ) memory comprising a plurality of spaced apart vertically extending layers characterized as word lines and a plurality of spaced apart horizontally extending rectilinear layers characterized as bit lines, wherein at each intersection of the respective vertically extending layers and horizontally extending rectilinear layers an FTJ memory cell is formed, each FTJ memory cell comprising a tunnel junction layer and the ferroelectric layer.

12. The apparatus of claim 11, wherein the horizontally extending rectilinear layers are planar and the vertically extending layers are cylindrical so that the respective tunnel junction and ferroelectric layers are concentric.

13. An apparatus comprising a non-volatile ferroelectric memory cell in a three-dimensional (3D) memory array in which nominally identical non-volatile ferroelectric memory cells are sequentially arranged in a spaced apart fashion along three orthogonal axes, each of the ferroelectric memory cells comprising:
a ferroelectric layer adapted to provide non-volatile storage of data;
a tunnel barrier layer contactingly engaging the ferroelectric layer; and
opposing first and second conductive layers between which the ferroelectric layer and the tunnel barrier are disposed, the first conductive layer coupled to the ferroelectric layer, the second conductive layer coupled to the tunnel barrier.

14. The apparatus of claim 13, wherein each ferroelectric memory cell is arranged as a ferroelectric field effect transistor (FeFET) comprising a source region, a drain region, and a control gate region, the control gate region comprising the ferroelectric layer, the first conductive layer attached to the source region, the second conductive layer attached to the drain region.

15. The apparatus of claim 13, wherein each ferroelectric memory cell is arranged as a ferroelectric tunnel junction (FTJ) comprising the tunnel barrier layer contactingly affixed to the ferroelectric layer, wherein the first conductive layer is a first electrode layer contactingly affixed to the ferroelectric layer and the second conductive layer is a second electrode layer contactingly affixed to the tunnel junction layer, and wherein the ferroelectric layer and the tunnel barrier layer are disposed between the first and second conductive layers.

16. The apparatus of claim 13, wherein the ferroelectric layer comprises at least a selected one of HfO2, ZrO2, or Hf1-xZxO2, and wherein the tunnel barrier layer comprises at least a selected one of Al2O3, MgO, or SrTiO3.

17. The apparatus of claim 13, wherein the memory is characterized as a 3D vertical gate (VG) NAND ferroelectric field effect transistor (FeFET) memory, the memory arranged as a plurality of vertically extending, planar gate structures intersected by a plurality of horizontally extending access control lines, wherein at least one FeFET is arranged at each intersection of the horizontally extending control lines and the vertically extending planar gate structures.

18. The apparatus of claim 13, wherein the memory is characterized as a 3D horizontal NOR (HNOR) ferroelectric field effect transistor (FeFET) memory, the memory arranged as a plurality of vertically extending layers configured to operate as word lines, a plurality of stacks of layers between adjacent pairs of the vertically extending layers, and a plurality of FeFETs at each connecting interface between an associated word line and an associated stack.

19. The apparatus of claim 13, wherein the memory is characterized as a vertical cross point ferroelectric tunnel junction (FTJ) memory, comprising a plurality of spaced apart vertically extending layers characterized as word lines and a plurality of spaced apart horizontally extending layers characterized as bit lines, wherein at each intersection of the respective vertically extending layers and the horizontally extending layers an FTJ memory cell is formed, each FTJ memory cell comprising a tunnel junction layer and the ferroelectric layer.

20. The apparatus of claim 13, wherein the memory is characterized as a vertical ferroelectric tunnel junction (FTJ) memory comprising a plurality of spaced apart vertically extending layers characterized as word lines and a plurality of spaced apart horizontally extending rectilinear layers characterized as bit lines, wherein at each intersection of the respective vertically extending layers and horizontally extending rectilinear layers an FTJ memory cell is formed, each FTJ memory cell comprising a tunnel junction layer and the ferroelectric layer.
